(19) United States
(12) Patent Application Publication
(10) Pub. No.: US 2015/0263026 A1
(43) Pub. Date: Sep. 17, 2015

(54) SEMICONDUCTOR DEVICE AND DESIGN APPARATUS FOR SEMICONDUCTOR DEVICE

(71) Applicant: Kabushiki Kaisha Toshiba, Minato-ku (JP)

(72) Inventors: Yuko KONO, Shinagawa-ku (JP); Ai Inoue, Yokohama-shi (JP); Toshiya Kotani, Machida-shi (JP); Chikaaki Kodama, Arakawa-ku (JP); Yasunobu Kai, Yokohama-shi (JP); Sadatoshi Murakami, Yokohama-shi (JP)

(73) Assignee: Kabushiki Kaisha Toshiba, Minato-ku (JP)

(21) Appl. No.: 14/340,666

(22) Filed: Jul. 25, 2014

Related U.S. Application Data
(60) Provisional application No. 61/951,911, filed on Mar. 12, 2014.

(51) Int. Cl. H01L 27/115; H01L 29/16; G06F 17/50; H01L 29/788; H01L 23/528; H01L 29/792; H01L 29/06

(52) U.S. Cl. CPC H01L 27/11568; H01L 29/792; H01L 29/16; H01L 29/0692; H01L 27/11565; H01L 29/788; H01L 27/11519; H01L 27/11521; H01L 23/528; G06F 17/5068

(57) ABSTRACT

According to one embodiment, a semiconductor device includes: a substrate including silicon; and a first element provided on the substrate and extending in a thickness direction of the substrate, a center position of an end face on the substrate side of the first element and a center position of an end face on an opposite side of the substrate side of the first element being different in a direction parallel to a major surface of the substrate.

### CROSS-REFERENCE TO RELATED APPLICATIONS

This application is based upon and claims the benefit of priority from U.S. Provisional Patent Application 61/951,911, filed on Mar. 12, 2014; the entire contents of which are incorporated herein by reference.

### FIELD

Embodiments described herein relate generally to a semiconductor device and a design apparatus for semiconductor device.

### BACKGROUND

In recent years, according to a request for refining of a semiconductor device, a pitch dimension of elements such as wires provided in the semiconductor device is decreasing.

In this case, the elements such as the wires are sometimes formed at a pitch dimension not more than a resolution limit in a lithography technique using a double patterning method or the like.

However, there is a demand for development of a technique that can more easily form contact holes, trenches, and the like and contact plugs, insulating layers embedded on the inside of the trenches, and the like at the pitch dimension not more than the resolution limit in the lithography technique.

### BRIEF DESCRIPTION OF THE DRAWINGS

FIG. 1A is a schematic perspective view for illustrating the semiconductor device 1;

FIG. 1B is a schematic sectional view for illustrating a contact plug 5 provided in the semiconductor device 1;

FIG. 2 is a schematic sectional view for illustrating a contact plug 105 according to a comparative example;

FIG. 3 is a schematic sectional view for illustrating the method of forming the contact plug 5;

FIG. 4 is a graph for illustrating the correlation between the tilt angle θ1 of the hole 50a and the tilt angle θ2 of the contact hole 25

FIG. 5A is schematic views for illustrating the control method for the tilt angle θ1 of the hole 50a;

FIG. 5B is schematic views for illustrating the control method for the tilt angle θ1 of the hole 50a;

FIG. 6 is a flowchart for illustrating the method of designing control patterns;

FIG. 7 is a schematic view for illustrating a calculation of the tilt angle θ1 of the hole 50a;

FIG. 8 is a flowchart for illustrating the method of designing the semiconductor device; and

FIG. 9 is a block diagram for illustrating a design apparatus 100 for a semiconductor device.

### DETAILED DESCRIPTION

In general, according to one embodiment, a semiconductor device includes: a substrate including silicon; and a first element provided on the substrate and extending in a thickness direction of the substrate, a center position of an end face on the substrate side of the first element and a center position of an end face on an opposite side of the substrate side of the first element being different in a direction parallel to a major surface of the substrate.

Embodiments are described below with reference to the drawings.

Note that a semiconductor device includes, for example, a memory device (a semiconductor memory device) and a logic device. As an example, a semiconductor device 1 according to the embodiment is a NAND flash memory, which is a type of the memory device.

In the drawings, the same components are denoted by the same reference numerals and signs and detailed description of the components is omitted as appropriate.

Arrows X, Y, and Z in the drawings represent three directions orthogonal to one another. For example, a direction perpendicular to a major surface 10a of a substrate 10 (e.g., the thickness direction of the substrate 10) is represented as Z-direction. One direction in a plane parallel to the major surface 10a of the substrate 10 is represented as X-direction. A direction perpendicular to the Z-direction and the X-direction is represented as Y-direction.

### First Embodiment

First, the semiconductor device 1 according to a first embodiment is illustrated.

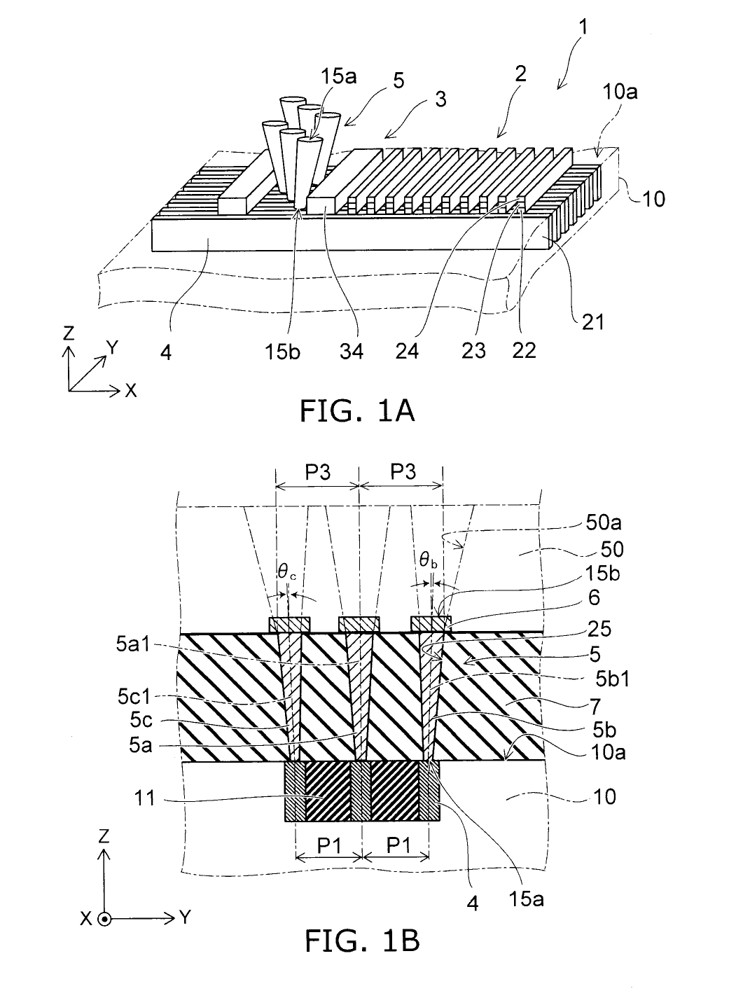

FIG. 1A is a schematic perspective view for illustrating the semiconductor device 1.

Note that, in FIG. 1A, to clearly show the figure, a portion of contact plugs of a NAND flash memory is shown. A part of elements included in the NAND flash memory are not shown. For example, bit lines, an insulating film, a control section, a row decoder, a sense amplifier, a column decoder, a data input/output circuit, and the like are not shown.

FIG. 1B is a schematic sectional view for illustrating a contact plug 5 provided in the semiconductor device 1.

As shown in FIG. 1A, in the semiconductor device 1, a memory cell transistor 2, a selection transistor 3, an active region 4, and the contact plug 5 are provided.

As shown in FIG. 1B, in the semiconductor device 1, a bit line 6 and an insulating film 7 are also provided.

The memory cell transistor 2 functions as a memory cell of the NAND flash memory.

The memory cell transistor 2 is provided on the major surface 10a of the substrate 10 including silicon.

The memory cell transistor 2 includes a gate insulating film 21, a charge storage layer 22, a block layer 23, and a control gate 24.

The control gate 24 extends in a direction (e.g., the Y-direction) crossing a direction in which the active region 4 extends (e.g., the X-direction).

That is, each of a plurality of the control gates 24 and each of a plurality of the active regions 4 cross each other.

In each of a plurality of positions where each of the plurality of control gates 24 and each of the plurality of active regions 4 cross, the memory cell transistor 2 is disposed.

A plurality of the memory cell transistors 2 share a source region and a drain region between the memory cell transistors 2 adjacent to each other in the direction in which the active region 4 extends. The drain region on one end side of the plurality of memory cell transistors 2 (NAND strings) connected in series in the direction in which the active region 4 extends is connected to the source region of the selection transistor 3. The source region on the other end side of the plurality of memory cell transistors 2 connected in series in the direction in which the active region 4 extends is connected to a drain region of a not-shown selection transistor.

The gate insulating film 21 is provided on the active region 4.

The gate insulating film 21 functions as a tunnel insulating film that causes charges (e.g., electrons) to tunnel-pass between the active region 4 and the charge storage layer 22.

The gate insulating film 21 can be formed of, for example, silicon oxide or silicon nitride.

The charge storage layer 22 is provided on the gate insulating film 21.

The charge storage layer 22 functions as a charge storage layer for storing charges.

The charge storage layer 22 can be formed of, for example, a semiconductor including n-type impurities. The charge storage layer 22 can be formed of, for example, polysilicon.

The block layer 23 is provided on the charge storage layer 22.

The block layer 23 confines charges in the charge storage layer 22.

The block layer 23 can be formed of, for example, an ONO film (a silicon oxide film/a silicon nitride film/a silicon oxide film).

The control gate 24 is provided on the block layer 23.

The control gate 24 functions as a gate electrode for controlling a transistor. The control gate 24 also functions as a word line.

The control gate 24 can be formed of, for example, a semiconductor including n-type impurities. The control gate 24 can be formed of, for example, polysilicon. The n-type impurities can be, for example, phosphorus or arsenic.

The selection transistor 3 includes the gate insulating film 21 and a control gate 34.

The control gate 34 is provided on the gate insulating film 21.

The control gate 34 extends in a direction same as the direction in which the control gate 24 extends (e.g., the Y-direction).

The control gate 34 functions as a gate electrode for controlling a transistor.

The control gate 34 can be formed of, for example, a semiconductor including the n-type impurities. The control gate 34 can be formed of, for example, polysilicon. The n-type impurities can be, for example, phosphorus or arsenic.

The plurality of active regions 4 are provided. Each of the plurality of active regions 4 is isolated by a device isolation layer 11 on a surface region of the substrate 10 (see FIG. 1B). The active region 4 isolated by the device isolation layer 11 has a stripe-like shape.

The active region 4 can be formed of, for example, a semiconductor including p-type impurities. The p-type impurities can be, for example, boron.

As shown in FIG. 1B, a plurality of the bit lines 6 are provided.

The bit line 6 extends in the direction in which the active region 4 extends.

The bit line 6 has a stripe-like form.

The bit line 6 can be formed of metal such as tungsten or copper.

As shown in FIG. 1B, the insulating film 7 covers the memory cell transistor 2, the selection transistor 3, the active region 4, and the contact plug 5.

The insulating film 7 can be formed of, for example, silicon oxide.

A plurality of the contact plugs 5 are provided.

The contact plug 5 can be formed of metal such as tungsten or copper.

As shown in FIG. 1B, each of the plurality of contact plugs 5 extends between each of the plurality of bit lines 6 and each of the plurality of active regions 4.

Each of one ends of the plurality of contact plugs 5 and each of the plurality of active regions 4 are connected.

Each of the other ends of the plurality of contact plugs 5 and each of the plurality of bit lines 6 are connected.

A sectional area on the active region 4 side of the contact plug 5 is smaller than a sectional area on the bit line 6 side of the contact plug 5.

For example, an area of an end face 15a on the active region 4 side of the contact plug 5 is smaller than an area of an end face 15b on the bit line 6 side of the contact plug 5.

A sectional area of the contact plug 5 can be set to gradually decrease toward the active region 4 side.

For example, the contact plug 5 can be tapered or sloped.

In a direction parallel to the major surface 10a of the substrate 10 (in plan view), center positions of both end faces can be set to overlap each other as in a contact plug 5a (equivalent to an example of a second element).

For example, a center axis 5a1 of the contact plug 5a can be set to be perpendicular to the major surface 10a of the substrate 10.

The contact plug 5a can have a form such as a right circular truncated cone shape or a right truncated pyramid shape. However, a form of the contact plug 5a is not limited to the illustrated form.

In the direction parallel to the major surface 10a of the substrate 10 (in plan view), center positions of both end faces can be set to shift from each other as in a contact plug 5b (equivalent to an example of a first element) and a contact plug 5c (equivalent to an example of the first element).

For example, center axes 5b1 and 5c1 of the contact plugs 5b and 5c may have predetermined angles θb and θc between the center axes 5b1 and 5c1 and a direction perpendicular to the major surface 10a of the substrate 10 (the Z-direction).

In this case, the contact plugs 5b and 5c can be set to tilt in a direction which end faces on the active region 4 side approach the contact plugs adjacent thereto.

The contact plugs 5b and 5c can be set to tilt in a direction in which end faces on the bit line 6 side recede from the contact plugs adjacent thereto.

The contact plugs 5b and 5c can be set to have a form such as an oblique circular truncated cone shape or an oblique truncated pyramid shape. However, a form of the contact plugs 5b and 5c is not limited to the illustrated form.

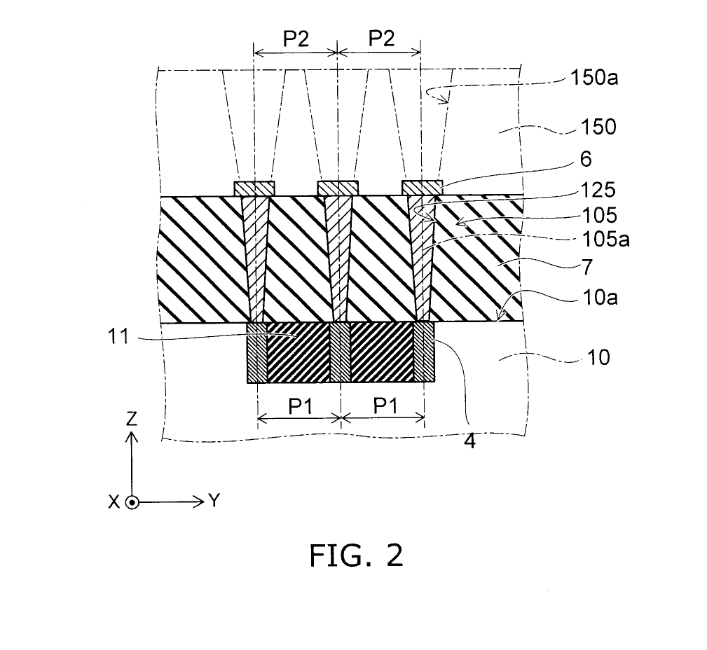

FIG. 2 is a schematic sectional view for illustrating a contact plug 105 according to a comparative example.

As shown in FIG. 2, each of a plurality of the contact plugs 105 extends between each of the plurality of bit lines 6 and each of the plurality of active regions 4.

A center axis 105a of the contact plug 105 passes the center of the bit line 6 and the center of the active region 4.

That is, in the direction parallel to the major surface 10a of the substrate 10 (in plan view), the center of the bit line 6, the center axis 105a of the contact plug 105, and the center of the active region 4 overlap one another.

When the contact plug 105 is formed, a resist mask 150 for forming a contact hole 125 is provided.

In this case, a pitch dimension P2 of a hole 150a of the resist mask 150 is the same as a pitch dimension P1 of the active region 4.

The active region 4 is sometimes formed at a pitch dimension not more than a resolution limit in a lithography technique using a double patterning method or the like.

When the pitch dimension P1 of the active region 4 is not more than the resolution limit in the lithography technique, the pitch dimension P2 of a pattern of the resist mask 150 is also not more than the resolution limit in the lithography technique.

Therefore, it is difficult to form the contact plug 105.

On the other hand, an end face on the active region 4 side of the contact plug 5 according to the embodiment tilts in a direction approaching the contact plug adjacent thereto.

Therefore, a pitch dimension P3 of a hole 50a of a resist mask 50 can be set to be longer than the pitch dimension P1 of the active region 4.

As a result, even if the pitch dimension P1 of the active region 4 is not more than the resolution limit in the lithography technique, the pitch dimension P3 of the hole 50a of the resist mask 50 can be set to be not less than the resolution limit in the lithography technique.

A sectional dimension of the hole 50a of the resist mask 50 increases toward the upper surface of the resist mask 50.

Therefore, even if the dimension of the active region 4 is not more than the resolution limit in the lithography technique, the sectional dimension of the hole 50a of the resist mask 50 can be set to be not less than the resolution limit in the lithography technique.

As a result, it is possible to easily form the contact plug 5.

Further, it is possible to realize refining and miniaturization of the semiconductor device 1.

### Second Embodiment

A method of forming the contact plug 5 according to a second embodiment is illustrated.

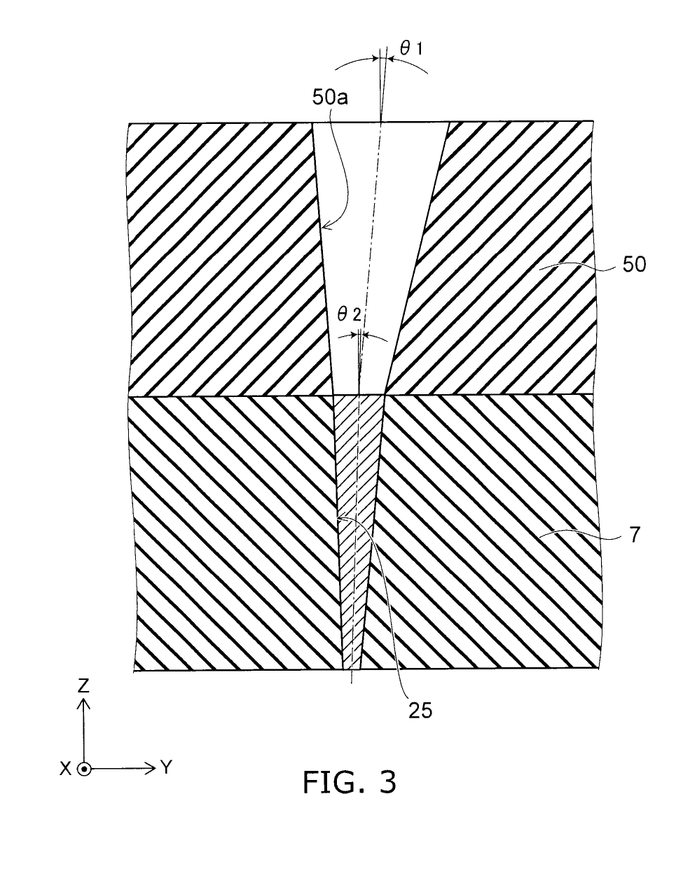

FIG. 3 is a schematic sectional view for illustrating the method of forming the contact plug 5.

According to the knowledge obtained by the inventors, when etching is performed using the resist mask 50 including the tilted hole 50a, a contact hole 25 can be tilted.

When metal such as tungsten is embedded in the tilted contact hole 25, the tilted contact plug 5 can be formed.

According to the knowledge obtained by the inventors, there is a correlation between a tilt angle θ1 of the hole 50a and a tilt angle θ2 of the contact hole 25.

The tilt angle θ1 of the hole 50a is an angle between the center axis of the hole 50a and the direction perpendicular to the major surface 10a of the substrate 10 (the Z-direction).

The tilt angle θ2 of the contact hole 25 is an angle between the center axis of the contact hole 25 and the direction perpendicular to the major surface 10a of the substrate 10 (the Z-direction).

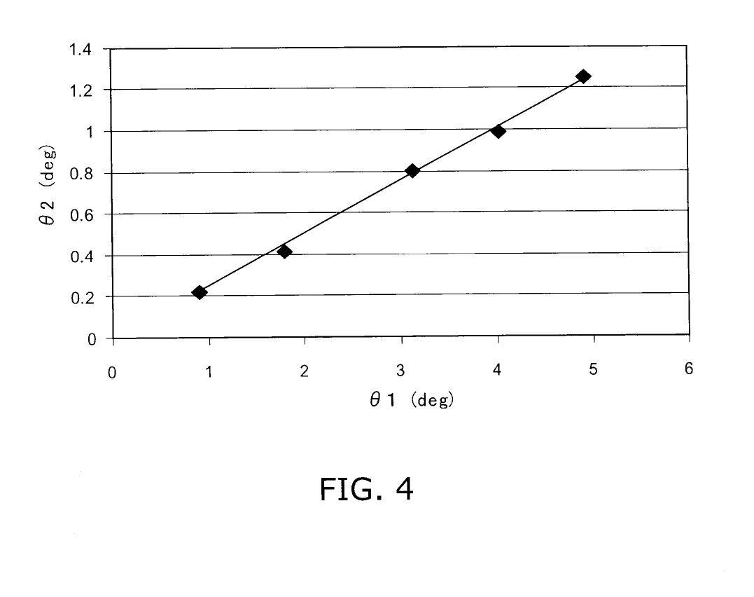

FIG. 4 is a graph for illustrating the correlation between the tilt angle θ1 of the hole 50a and the tilt angle θ2 of the contact hole 25.

As shown in FIG. 4, there is a positive correlation between the tilt angle θ1 of the hole 50a and the tilt angle θ2 of the contact hole 25.

The tilt angle θ1 of the hole 50a and the tilt angle θ2 of the contact hole 25 have a liner correlation.

Therefore, by controlling the tilt angle θ1 of the hole 50a, the tilt angle θ2 of the contact hole 25 and a tilt angle of the contact plug 5 can be set to desired angles.

Note that the correlation between the tilt angle θ1 of the hole 50a and the tilt angle θ2 of the contact hole 25 is not limited to the illustrated correlation.

The correlation between the tilt angle θ1 of the hole 50a and the tilt angle θ2 of the contact hole 25 may be affected by, for example, conditions (e.g., the thickness, the material, and process conditions of a film to be etched) of etching.

Therefore, the correlation between the tilt angle θ1 of the hole 50a and the tilt angle θ2 of the contact hole 25 is obtained by performing an experiment, a simulation, or the like in advance.

A control method for the tilt angle θ1 of the hole 50a of the resist mask 50 is described.

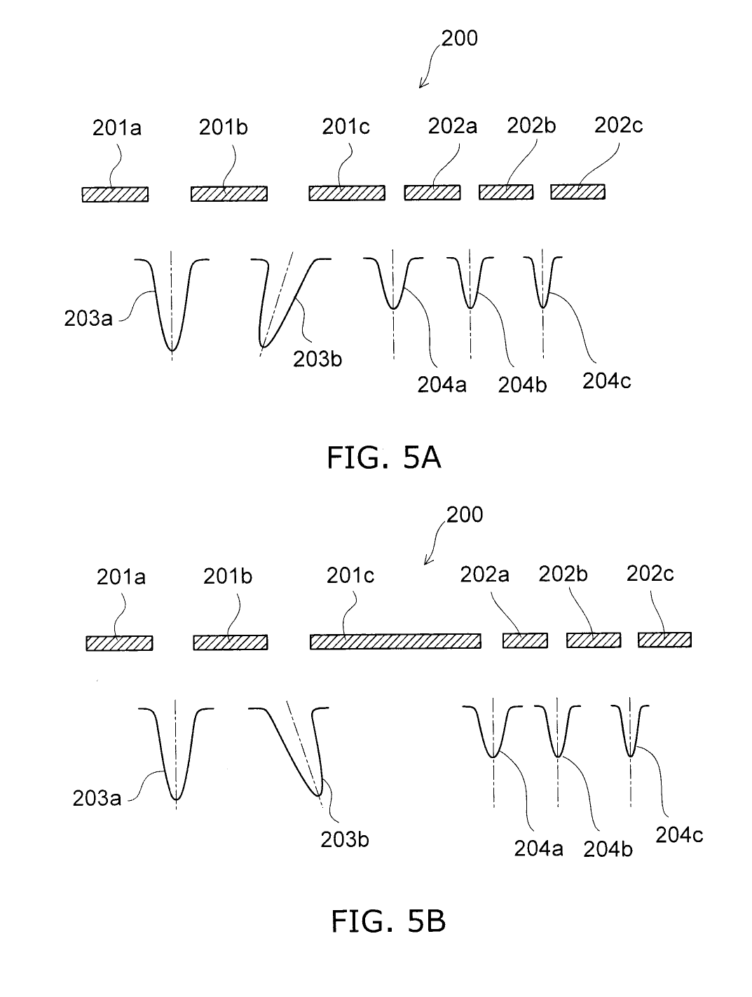

FIGS. 5A and 5B are schematic views for illustrating the control method for the tilt angle θ1 of the hole 50a.

As shown in FIGS. 5A and 5B, patterns 201a to 201c (main patterns) for forming the contact hole 25 and control patterns 202a to 202c for performing control of the tilt angle θ1 of the hole 50a are provided on a photomask 200.

Note that the control patterns 202a to 202c are not transferred onto the resist mask 50. For example, the control patterns 202a to 202c have a dimension not more than the resolution limit in the lithography technique.

The control patterns 202a to 202c optically modulate an optical image formed by the patterns 201a to 201c.

Therefore, an optical image intensity distribution 203b formed by the patterns 201b and 201c provided in the vicinity of the control patterns 202a to 202c tilts.

In this case, as shown in FIG. 5A, when the distance between the control patterns 202a to 202c and the patterns 201b and 202c is short, the optical image intensity distribution 203b tilts in a direction in which the distal end thereof recedes from the control patterns 202a to 202c.

As shown in FIG. 5B, when the distance between the control patterns 202a to 202c and the patterns 201b and 202c is long, the optical image intensity distribution 203b tilts in a direction in which the distal end thereof approaches the control patterns 202a to 202c.

In this case, an optical image intensity distribution 203a formed by the patterns 201a and 201b present in positions apart from the control patterns 202a to 202c does not tilt or, even if the optical image intensity distribution 203a tilts, a tilt angle is small.

Optical image intensity distributions 204a to 204c are formed by the control patterns 202a to 202c. A tilt angle of the optical image intensity distribution 203b is affected by the optical image intensity distributions 204a to 204c. In this case, the influence of the optical image intensity distribution 204a closest to the optical image intensity distribution 203b is the strongest. The influence of the optical image intensity distribution 204a most distant from the optical image intensity distribution 203b is the weakest.

Therefore, the tilt angle θ1 of the hole 50a of the resist mask 50 can be controlled according to the arrangement of the control patterns (the distance between the patterns for forming the contact holes 25 and the control patterns), the number of the control patterns, the size of the control patterns, and the like.

### Third Embodiment

A method of designing control patterns according to a third embodiment is illustrated.

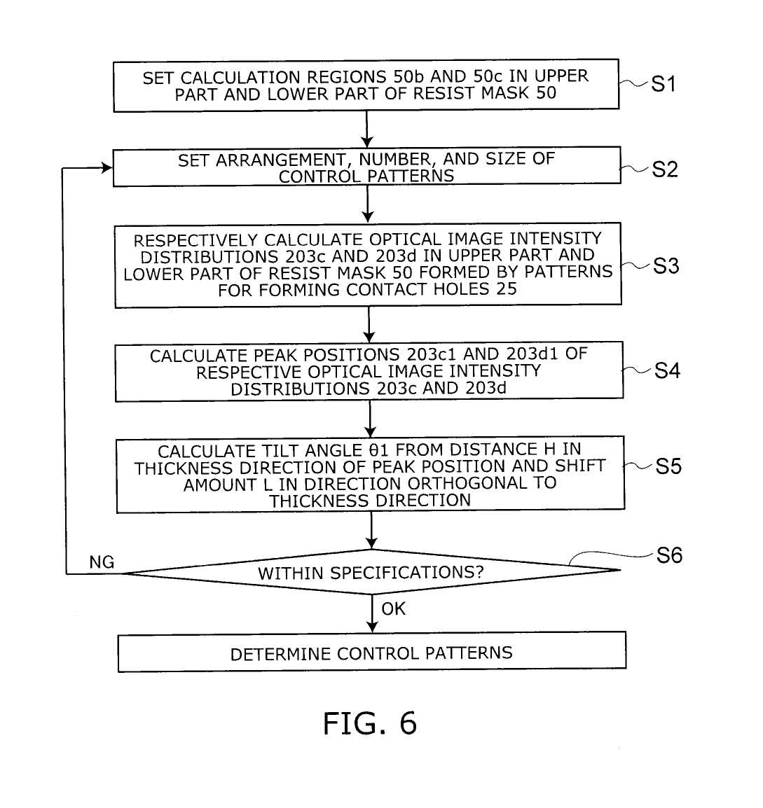

FIG. 6 is a flowchart for illustrating the method of designing control patterns.

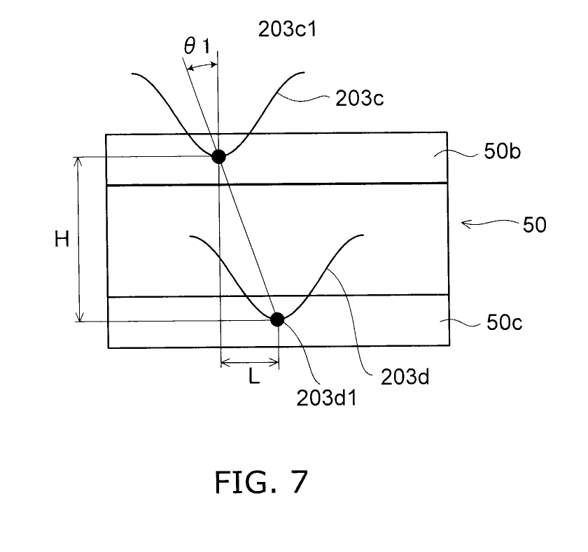

FIG. 7 is a schematic view for illustrating a calculation of the tilt angle θ1 of the hole 50a.

As shown in FIGS. 6 and 7, first, calculation regions 50b and 50c are set in an upper part and a lower part of the resist mask 50 (step S1).

Subsequently, the arrangement, the number, and the size of control patterns are set (step S2).

Subsequently, optical image intensity distributions 203c and 203d in the upper part and the lower part of the resist mask 50 formed by patterns for forming the contact hole 25 are respectively calculated (step S3).

The optical image intensity distributions 203c and 203d are calculated taking into account optical modulation due to the set control patterns.

The optical image intensity distributions 203c and 203d can be calculated by performing an optical simulation.

Subsequently, respective peak positions 203c1 and 203d1 of the optical image intensity distributions 203c and 203d are calculated (step S4).

Subsequently, the tilt angle θ1 is calculated from a distance H in the thickness direction of the peak positions and a shift amount L in a direction orthogonal to the thickness direction of the peak positions (step S5).

Subsequently, it is determined whether the calculated tilt angle θ1, setting conditions for the control patterns, and the like are within specifications (step S6).

When the calculated tilt angle θ1, the setting conditions for the control patterns, and the like are within specifications, the arrangement, the number, and the size of the control patterns can be determined.

When the calculated tilt angle θ1, the setting conditions for the control patterns, and the like are not within specifications, the processing returns to step S2.

As described above, the design of the control patterns can be performed.

### Fourth Embodiment

A method of designing a semiconductor device according to a fourth embodiment is illustrated.

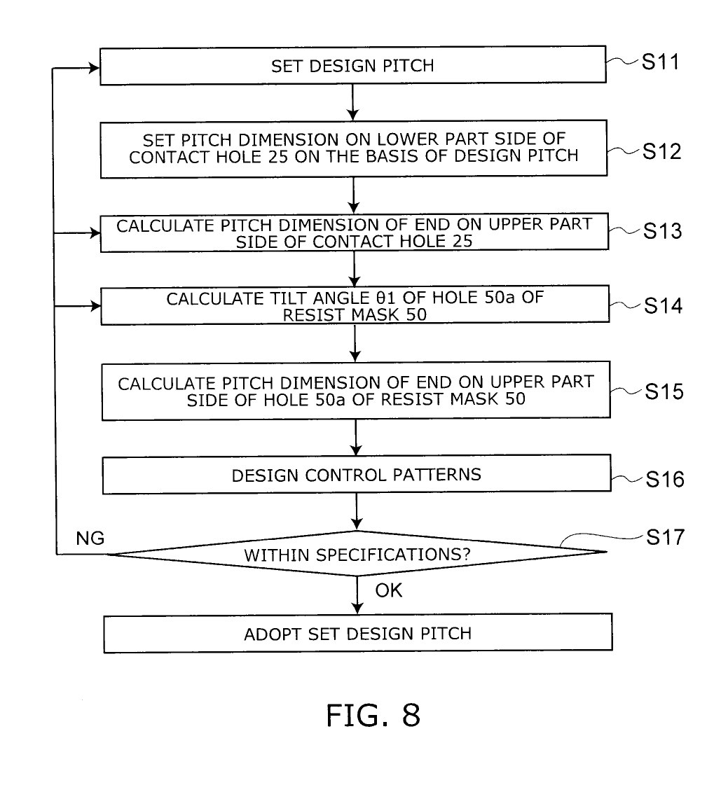

FIG. 8 is a flowchart for illustrating the method of designing the semiconductor device.

As shown in FIG. 8, first, a design pitch is set (step S11).

In the semiconductor device described above, the design pitch is, for example, the pitch dimension P1 of the active region 4.

Subsequently, a pitch dimension of an end face on a lower part side (e.g., the active region 4 side) of the contact hole 25 is set on the basis of the design pitch (step S12).

Subsequently, the pitch dimension of the end face on an upper part side (e.g., the bit line 6 side) of the contact hole 25 is calculated (step S13).

The tilt angle θ2 of the contact hole 25 is set taking into account, for example, conditions (e.g., the thickness, the material, and process conditions of a film to be etched) of etching.

The pitch dimension of the end face on the upper part side of the contact hole 25 is calculated from the pitch dimension of the end face on the lower part side of the contact hole 25, the tilt angle θ2 of the contact hole 25, and the thickness of the film to be etched.

The pitch dimension of the end face on the upper part side of the contact hole 25 can be set to a pitch dimension of an end on a lower part side of the hole 50a of the resist mask 50.

Subsequently, the tilt angle θ1 of the hole 50a of the resist mask 50 is calculated (step S14).

The tilt angle θ1 can be calculated on the basis of the correlation between the tilt angle θ1 and the tilt angle θ2 described above.

Subsequently, a pitch dimension of an end on an upper part side of the hole 50a of the resist mask 50 is calculated (step S15).

For example, the pitch dimension of the end on the upper part side of the hole 50a of the resist mask 50 is calculated from the pitch dimension of the end on the lower part side of the hole 50a of the resist mask 50, the tilt angle θ1 of the hole 50a of the resist mask 50, and the thickness of the resist mask 50.

Subsequently, control patterns are designed (step S16).

For example, the arrangement, the number, and the size of the control patterns for setting the tilt angle θ1 of the hole 50a of the resist mask 50 to the value obtained in step S14 are calculated.

The arrangement, the number, and the size of the control pattern can be calculated by performing an optical simulation.

Subsequently, it is determined whether the calculated control patterns are within predetermined specifications (step S17).

When the control patterns are within the specifications, proper control patterns can be provided.

Therefore, the set design pitch can be realized. Therefore, the set design pitch is adopted together with the designed control patterns.

When the control patterns are not within the specifications, the processing returns to steps S11, S13, and S14.

As described above, it is possible to design a semiconductor device having a desired design pitch.

### Fifth Embodiment

An exposing method according to a fifth embodiment is illustrated.

First, a resist layer having predetermined thickness is formed on the substrate 10.

The thickness of the resist layer can be set on the basis of the thickness of the resist mask 50 used in the method of designing the semiconductor device described above.

Subsequently, patterns are transferred onto the resist layer using a photomask created on the basis of an adopted design pitch and control patterns.

Subsequently, the resist layer, onto which the patterns are transferred, is developed to form the resist mask 50.

### Sixth Embodiment

A design apparatus for a semiconductor device according to a sixth embodiment is illustrated.

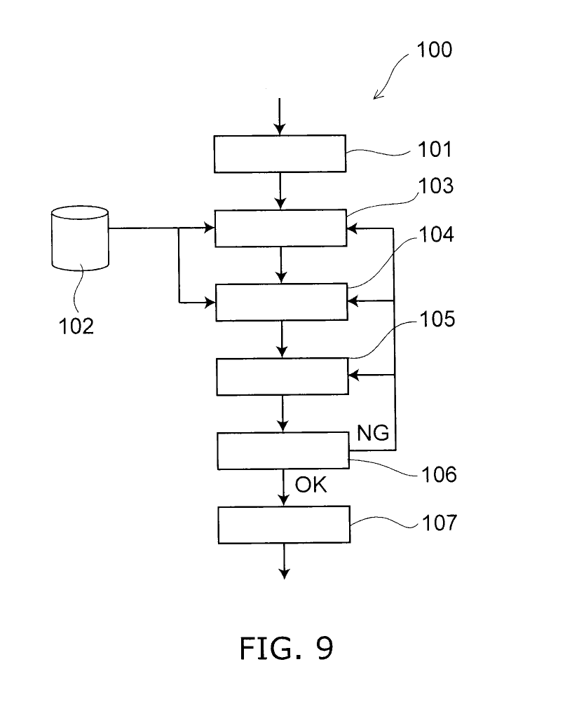

FIG. 9 is a block diagram for illustrating a design apparatus 100 for a semiconductor device.

The design apparatus 100 for the semiconductor device can carry out the method of designing the semiconductor device described above.

As shown in FIG. 9, the design apparatus 100 of the semiconductor device includes an input unit 101, a design-data storing unit 102, an element designing unit 103, a resist-mask designing unit 104, a photomask designing unit 105, a determining unit 106, and an output unit 107.

The input unit 101 inputs design specifications of the semiconductor device to the element designing unit 103.

The design specifications of the semiconductor device are, for example, a design pitch.

In the semiconductor device described above, the design pitch is, for example, the pitch dimension P1 of the active region 4.

The design-data storing unit 102 stores various data necessary for designing of the semiconductor device.

In the semiconductor device described above, the data necessary for designing of the semiconductor device are, the tilt angle θ1 of the hole 50a of the resist mask 50, the tilt angle θ2 of the contact hole 25, the correlation between the tilt angle θ1 and the tilt angle θ2, and the like.

In this case, the tilt angle θ2 is specified taking into account, for example, conditions (e.g., the thickness, the material, and process conditions of a film to be etched) of etching.

Besides, the thickness of the film to be etched, the thickness of the resist mask 50, and the like can also be stored.

The data stored in the design-data storing unit 102 can be calculated by performing an experiment or a simulation in advance.

The element designing unit 103 designs an element extending in the thickness direction of the substrate 10.

In this case, the element designing unit 103 can design an element, the center position of an end face on the substrate 10 side of which and the center position of an end face on the opposite side of the substrate 10 side of which are different in a direction parallel to the major surface 10a of the substrate 10.

In the semiconductor device described above, the element extending in the thickness direction of the substrate 10 is the contact plug 5.

In the following description, the element extending in the thickness direction of the substrate 10 is the contact plug 5.

First, the element designing unit 103 sets, on the basis of a design pitch input from the input section 101, a center position and a pitch dimension of an end face on a lower part side (e.g., the active region 4 side) of the contact hole 25.

Subsequently, the element designing unit 103 calculates a center position and a pitch dimension of an end face on an upper part side (e.g., the bit line 6 side) of the contact hole 25.

For example, the element designing unit 103 calculates a center position and a pitch dimension of the end face on the upper part side of the contact hole 25 from the center position and the pitch dimension of the end face on the lower part side of the contact hole 25, the tilt angle θ2 of the contact hole 25 provided from the design-data storing unit 102, and the thickness of the film to be etched.

The resist-mask designing unit 104 designs a resist mask.

In the semiconductor device described above, the resist-mask designing unit 104 designs the resist mask 50 including the tilted hole 50a.

First, the resist-mask designing unit 104 calculates the tilt angle θ1 of the hole 50a of the resist mask 50.

For example, the resist-mask designing unit 104 calculates the tilt angle θ1 of the hole 50a from the tilt angle θ2 of the contact hole 25 (the contact plug 5) used in the element designing unit 103 and the correlation between the tilt angle θ1 and the tilt angle θ2 provided from the design-data storing unit 102.

Subsequently, the resist-mask designing unit 104 calculates a center position and a pitch dimension of the end face on the upper part side of the hole 50a of the resist mask 50.

For example, the resist-mask designing unit 104 calculates a center position and a pitch dimension of the end face on the upper part side of the hole 50a of the resist mask 50 from the calculated tilt angle θ1 of the hole 50a, the center position and the pitch dimension of the end face on the lower part side of the hole 50a of the resist mask 50, and the thickness of the resist mask 50 provided from the design-data storing unit 102.

In this case, the center position and the pitch dimension of the end face on the lower part side of the hole 50a of the resist mask 50 can be set to the center position and the pitch dimension of the end face on the upper part side of the contact hole 25 calculated in the element designing unit 103.

The photomask designing unit 105 designs a photomask for forming the resist mask designed in the resist-mask designing unit 104.

For example, the photomask designing unit 105 designs the control patterns 202a to 202c such that the hole 50a having the tilt angle θ1 designed in the resist-mask designing unit 104 is formed in the resist mask 50. For example, the photomask designing unit 105 designs at least any one of the arrangement, the number, and the size of the control patterns 202a to 202c.

The arrangement, the number, and the size of the control patterns 202a to 202c can be calculated by performing an optical simulation.

Note that the control patterns 202a to 202c optically modulate an optical image concerning the hole 50a having the tilt angle θ1. However, the control patterns 202a to 202c are not transferred onto the resist mask 50.

The determining unit 106 determines whether the element designed in the element designing unit 103, the resist mask designed in the resist-mask designing unit 104, and the photomask designed in the photomask designing unit 105 are within predetermined specifications.

When the element, the resist mask, and the photomask are within the predetermined specifications, data concerning the element, the resist mask, and the photomask is sent to the output unit 107.

When the element, the resist mask, and the photomask are not within the predetermined specifications, the designing is performed again.

The output unit 107 outputs the data concerning the element, the resist mask, and the photomask to an external apparatus.

The external apparatus is, for example, a manufacturing apparatus for a photomask, an exposure apparatus, or a database.

Note that, in the above description, the contact plug 5 is illustrated as the element extending in the thickness direction of the substrate 10. However, the element extending in the thickness direction of the substrate 10 is not limited to this.

The element extending in the thickness direction of the substrate 10 may be any element as long as the element is provided on the substrate 10 and extends in the thickness direction of the substrate 10 (the Z-direction). For example, the element can also be applied to a trench, an insulating layer embedded in the trench, and the like.

The semiconductor device 1 including the plurality of memory cell transistors 2 disposed in the directions (the X-direction and the Y-direction) parallel to the major surface 10a of the substrate 10 is illustrated as the semiconductor device according to the present invention. The semiconductor device is not limited to this.

The semiconductor device can be a semiconductor device including the plurality of memory cell transistors 2 stacked in the thickness direction of the substrate 10 (the Z-direction).

The semiconductor device is not limited to the semiconductor device including the memory cell transistor 2.

For example, the semiconductor device may be a logic device and the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a substrate including silicon; and
a first element provided on the substrate and extending in a thickness direction of the substrate, a center position of an end face on the substrate side of the first element and a center position of an end face on an opposite side of the substrate side of the first element being different in a direction parallel to a major surface of the substrate.

2. The device according to claim 1, wherein
a plurality of the first elements are provided, and
one of the first elements tilts in a direction in which an end face on the substrate side of the first element approaches the other of the first elements.

3. The device according to claim 1, wherein
a plurality of the first elements are provided, and
one of the first elements tilts in a direction in which an end face on an opposite side of the substrate side of the first element recedes from the other of the first elements.

4. The device according to claim 1, wherein a sectional area of the end face on the substrate side of the first element is smaller than a sectional area of the end face on the opposite side of the substrate side of the first element.

5. The device according to claim 1, wherein a sectional area of the first element gradually decreases toward the substrate side.

6. The device according to claim 1, wherein the first element has a tapered form.

7. The device according to claim 1, wherein the first element has a sloped form.

8. The device according to claim 1, further comprising a memory cell transistor provided on the substrate.

9. The device according to claim 8, wherein the end face on the substrate side of the first element is connected to at least one side of a drain side and a source side of the memory cell transistor.

10. The device according to claim 8, wherein the end face on the opposite side of the substrate side of the first element is connected to at least one side of a drain side and a source side of the memory cell transistor.

11. The device according to claim 1, further comprising a second element provided on the substrate and extending in the thickness direction of the substrate, a center position of an end face on the substrate side of the second element and a center position of an end face on an opposite side of the substrate side of the second element being same in the direction parallel to the major surface of the substrate.

12. The device according to claim 11, wherein the end face on the substrate side of the first element is provided in a direction in which the end face approaches the second element.

13. The device according to claim 11, wherein the end face on the opposite side of the substrate side of the first element is provided in a direction in which the end face recedes from the second element.

14. The device according to claim 1, wherein the first element is a contact plug or an insulating layer embedded in an inside of a trench.

15. The device according to claim 11, wherein the second element is a contact plug or an insulating layer embedded in an inside of a trench.

16. A design apparatus for a semiconductor device comprising an element designing unit that designs a first element provided on a substrate including silicon and extending in a thickness direction of the substrate, a center position of an end face on the substrate side of the first element and a center position of an end face on an opposite side of the substrate side of the first element being different in a direction parallel to a major surface of the substrate.

17. The apparatus according to claim 16, further comprising a resist-mask designing unit that designs a resist mask for forming the designed first element, wherein
the resist-mask designing unit calculates a tilt angle of a hole of the resist mask from a tilt angle of the designed first element and a correlation between the tilt angle of the first element and the tilt angle of the hole of the resist mask and calculates a center position of an end on an opposite side of the substrate side of the hole from the calculated tilt angle of the hole, the center position of the end face on the opposite side of the substrate side of the designed first element, and a thickness dimension of the resist mask.

18. The apparatus according to claim 17, further comprising a photomask designing unit that designs a photomask for forming the designed resist mask, wherein
the photomask designing unit designs a control pattern for optically modulating an optical image concerning a hole having the tilt angle such that the hole having the tilt angle calculated in the resist-mask designing unit is formed in the resist mask.

19. The apparatus according to claim 18, wherein the photomask designing unit designs at least any one of an arrangement, a number, and a size of the control pattern.

20. The apparatus according to claim 18, wherein the control pattern is not transferred onto the resist mask.
